(19) United States
(12) Patent Application Publication
(10) Pub. No.: US 2012/0164354 A1
(43) Pub. Date: Jun. 28, 2012

(54) SPUTTERING APPARATUS AND MANUFACTURING METHOD OF ELECTRONIC DEVICE

(75) Inventors: Yuichi Otani, Tokyo (JP); Nobuo Yamaguchi, Tokyo (JP)

(73) Assignee: CANON ANELVA CORPORATION, Kawasaki-shi (JP)

(21) Appl. No.: 13/315,576

(22) Filed: Dec. 9, 2011

(30) Foreign Application Priority Data
Dec. 28, 2010 (JP) 2010-293527
Nov. 7, 2011 (JP) 2011-243539

(51) Int. Cl. C23C 14/34

(52) U.S. Cl. 427/580; 118/620

(57) ABSTRACT

The present invention provides a sputtering apparatus that can efficiently laminate thin films in a short time without lowering throughputs, and a manufacturing method of an electronic device. The sputtering apparatus according to an embodiment of the present invention includes a rotatable substrate holder, four target holders obliquely arranged with respect to the substrate holder, and a first shutter and a second shutter that each are provided between the target holders and the substrate holder and have two holes arranged two-fold symmetrical with respect to a rotational axis X. Two of the four target holders are first group target holders arranged two-fold symmetrical with respect to the rotational axis X, and the other two target holders are second group target holders arranged between the first group target holders and two-fold symmetrical with respect to the rotational axis X.

### CROSS-REFERENCES TO RELATED APPLICATIONS

This application claims the benefit of Japanese Patent Application Nos. 2010-293527, filed Dec. 28, 2010 and 2011-243539, filed Nov. 7, 2011. The contents of the aforementioned applications are incorporated herein by reference in their entirety.

### BACKGROUND OF THE INVENTION

1. Field of the Invention

The present invention relates to a sputtering apparatus and a manufacturing method of an electronic device.

2. Description of the Related Art

To form a uniform ultrathin film by sputtering, a so-called oblique sputtering film formation method of obliquely injecting sputtering particles to a rotating substrate to form a film has been conventionally employed. Japanese Patent Application Laid-Open No. 2009-68075 discloses a sputtering apparatus including a plurality of targets and a shutter plate having a plurality of openings with respect to a substrate.

In recent years, to manufacture a magnetic random access memory (MRAM) attracting attention as a next-generation nonvolatile memory, lamination of an insulating layer, a metal layer and the like, which have thickness of about a few nanometers, has been demanded. A storage unit of the MRAM has a three-layered structure in which an insulating material is sandwiched with magnetic materials, and information can be defined according to magnetic alignment state of a magnetic layer (parallel or antiparallel state).

In the conventional MRAM, the magnetization direction of the magnetic layer is parallel to the substrate. However, in recent years, a vertical-type MRAM including a magnetic layer having the vertical magnetization direction (vertical magnetic film) has been proposed in terms of scaling and low power consumption.

An alloy material such as TbFeCo, FePt and CoPt is used for the vertical magnetic film included in the vertical-type MRAM. Examples of main thin film preparing method using the alloy material include sputtering using an alloy target, cosputtering of simultaneously discharging a plurality of different types of metal targets, and a method of forming a film according to alternate sputtering of alternately forming a film using the plurality of different types of metal targets and forming ordered alloy by heat treatment. However, in order to achieve uniform ordered alloy in the plane of the formed film, it is needed to make composition ratio before heat treatment, film thickness distribution and the like uniform. Therefore, alternate sputtering is considered to be suitable for preparing the vertical magnetic film in the vertical-type MRAM.

According to the alternate sputtering technique in the vertical-type MRAM, it is demanded to efficiently form a laminated film obtained by repeatedly laminating a thin film having a thickness of 1 nm or less. As disclosed in Japanese Patent Application Laid-Open No. 2009-68075, according to the conventional oblique sputtering film formation method, when such thin film is formed while the substrate is rotated, start and end of film formation is controlled by opening/closing a shutter for shielding the target. Generally, discharging is performed with the shutter being closed prior to film formation on the substrate, and after impurities on the surface of the target are removed, the shutter is opened while maintaining discharging. Thereby, film formation is started. Therefore, film formation is continued even while the target is exposed to the substrate and the shielding shutter is opened/closed and thus, the film formation rate during the period is unstable. When film formation time having a sufficiently large number of revolutions of the substrate is ensured, the phenomenon that the film formation rate is unstable does not matter. However, in mass production of the MRAM, throughputs must be improved. For this reason, although it is needed to shorten the film formation time (for example, three to six seconds per layer), the total number of revolutions of the substrate is small in such short time, resulting in that the shutter opening/closing time occupied in the film formation time cannot be ignored. Since the film formed before opening of the shutter and the film formed after complete opening of the shutter are mixed, in-plane distribution becomes disadvantageously nonuniform. In addition, although such problem can be solved by rotating the substrate holder at higher speed, the speed of a motor for rotating the substrate holder has already reached a physical limit.

### SUMMARY OF THE INVENTION

Thus, the present invention is made in consideration of the conventional problem and provides a sputtering apparatus that can efficiently laminate thin films in a short time without lowering throughputs, and a manufacturing method of an electronic device using the sputtering apparatus.

In order to attain the object, first aspect o the present invention is a sputtering apparatus comprising: a treatment chamber; a substrate holder for holding a substrate, the substrate holder being provided in the treatment chamber and being configured so as to be rotatable about a rotational axis perpendicular to a film formation surface of the substrate; a target holder group provided in the treatment chamber, the target holder group configured to be capable of holding a target and provided so that the rotational axis does not match a perpendicular line passing the center of the target; and a shutter provided between the target holder group and the substrate holder, the shutter being capable of rotating about the rotational axis and having n holes arranged n-fold symmetrical with respect to the rotational axis, wherein the target holder group includes n first group target holders arranged n-fold symmetrical with respect to the rotational axis and n second group target holders arranged n-fold symmetrical with respect to the rotational axis, each of the second group target holders being provided between the first group target holders, and each of the n first group target holders overlaps each of the n holes at a first rotational position of the n holes, and each of the n second group target holders overlaps each of the n holes at a second rotational position of the n holes.

Second aspect of the present invention is a manufacturing method of an electronic device using a sputtering apparatus including: a treatment chamber; a substrate holder for holding a substrate, the substrate holder being provided in the treatment chamber and being configured so as to be rotatable about a rotational axis perpendicular to a film formation surface of the substrate; a target holder group provided in the treatment chamber, the target holder group configured to be capable of holding a target and provided so that the rotational axis does not match a perpendicular line passing the center of the target; and a shutter provided between the target holder group and the substrate holder, the shutter being capable of rotating about the rotational axis and having n holes arranged n-fold symmetrical with respect to the rotational axis, wherein he target holder group includes n first group target holders arranged n-fold symmetrical with respect to the rotational axis and n second group target holders arranged n-fold symmetrical with respect to the rotational axis, each of the second group target holders being provided between the first group target holders, and ach of the n first group target holders overlaps each of the n holes at a first rotational position of the n holes, and each of the n second group target holders overlaps each of the n holes at a second rotational position of the n holes, he manufacturing method comprising: first preparation step of starting rotation of the substrate holder; second preparation step of supplying first electric power to the first group target holders and supplying second electric power to the second group target holders, first film formation step of positioning the n holes in the shutter as opposed to the first group target holders; and second film formation step of positioning the n holes in the shutter as opposed to the second group target holders.

According to the present invention, it is possible to provide a sputtering apparatus that can efficiently laminate thin films in a short time without lowering throughputs, and a manufacturing method of an electronic device using the sputtering apparatus.

### BRIEF DESCRIPTION OF THE DRAWINGS

FIG. 1 is a schematic sectional view illustrating configuration of a sputtering apparatus according to an embodiment of the present invention.

FIG. 2 is a top view showing target holders according to the embodiment of the present invention.

FIG. 3A is a view illustrating configuration of shutters when shielding targets according to the embodiment of the present invention.

FIG. 3B is a view illustrating configuration of the shutters in a first film formation step according to the embodiment of the present invention.

FIG. 3C is a view illustrating configuration of the shutters in a second film formation step according to the embodiment of the present invention.

FIG. 4 is a schematic plan view illustrating positional relationship between holes of the shutter and the target according to the embodiment of the present invention.

FIG. 5 is a view illustrating film formation process flow according to the embodiment of the present invention.

FIG. 6 is a view illustrating flow of a first film formation step and a second film formation step according to the embodiment of the present invention.

FIG. 7 is a view illustrating the flow of the first film formation step and the second film formation step according to the embodiment of the present invention.

FIG. 8 is a sectional view illustrating configuration of a film manufactured in the film formation process in FIG. 5.

FIG. 9 is a view illustrating in-plane distribution of a film formed by an oblique sputtering film formation method as a comparative example.

FIG. 10 is a view illustrating in-plane distribution of a film formed by a sputtering film formation method according to the embodiment of the present invention.

FIG. 11 is a plan view illustrating three-fold symmetrically arranged target holders according to the embodiment of the present invention.

FIG. 12 is a block diagram showing schematic configuration of a control system in the sputtering apparatus according to the embodiment of the present invention.

### DESCRIPTION OF THE EMBODIMENTS

An embodiment for implementing the present invention will be described below with reference to figures.

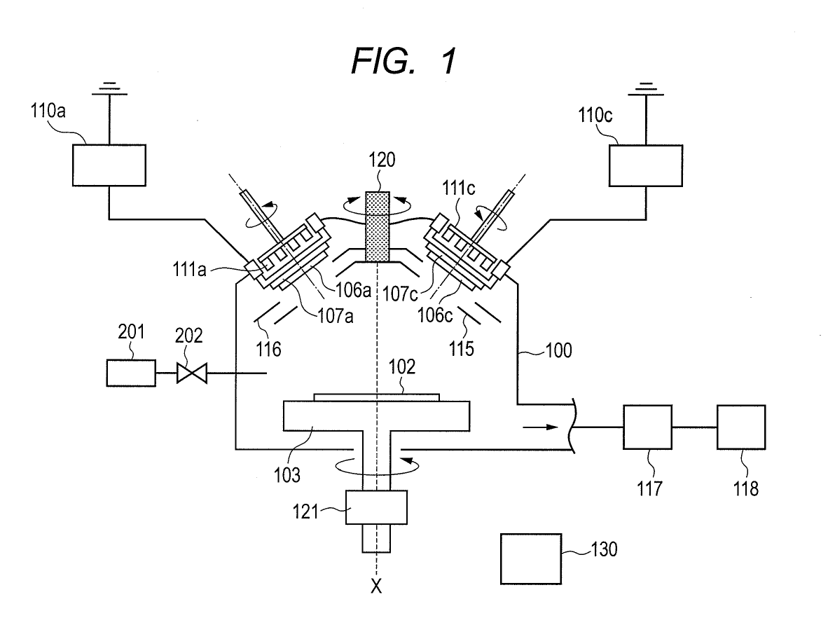

Referring to FIG. 1, a sputtering apparatus according to an embodiment of the present invention will be described.

The sputtering apparatus can manufacture an electronic device such as MRAM. The sputtering apparatus includes a treatment chamber 100, a substrate holder 103 for holding a substrate, the substrate holder 103 being provided in the treatment chamber so as to be rotatable about a rotational axis perpendicular to a film formation surface of the substrate, a rotation driving part 121 as a rotation driving means for rotating the substrate holder 103, and a target holder group having target holders 107a to 107d provided so that a perpendicular line which is perpendicular to a plane including the film formation surface of the substrate and which passes the center of the substrate, does not match a perpendicular line passing the center of a target. Each of the target holders 107a to 107d is configured to be able to hold the target, is formed of a metal member and functions as an electrode. The sputtering apparatus further includes DC power sources as power supply means for supplying electric power to each target holder. That is, the DC power sources 110a to 110d are connected to the target holders 107a to 107d, respectively. In FIG. 1, only the DC power source 110a for supplying electric power to the target holder 107a and the DC power source 110c for supplying electric power to the target holder 107c are shown.

Rotatable magnet units 111a, 111c are provided behind the target holders 107a and 107c, respectively. Similar magnet units to the magnet units 111a, 111c are also provided behind the target holders 107b and 107d. The treatment chamber 100 is provided with a gas introducing part 201 as a gas introducing means for introducing process gas (in this example, inert gas such as argon gas) via a gate valve 202. The treatment chamber 100 is also provided with an exhaust pump 118 via a conductance valve 117.

Targets 106a to 106d are installed at the target holders 107a to 107d, respectively. Two shutters: a first shutter 115 and a second shutter 116 that can shield a substrate 102 against sputtering particles are provided in front of the targets 106a to 106d (that is, between the target holders 107a to 107d and the substrate holder 103). The first shutter 115 and the second shutter 116 are configured to be able to be individually driven by a shutter driving part 120 as a shutter driving means.

The DC power sources 110a to 110d, the shutter driving part 120 and the rotation driving part 121 are configured to be able to be controlled by a control part 130 as a control means electrically connected thereto.

FIG. 12 is a block diagram showing schematic configuration of the control part 130 in the sputtering apparatus in this embodiment.

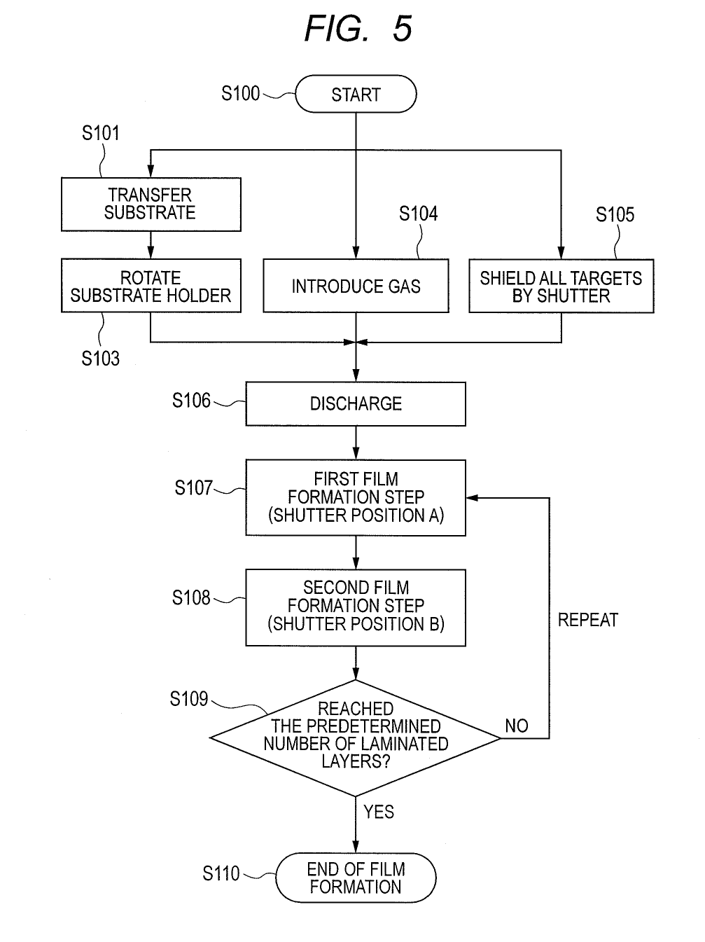

In FIG. 12, the control part 130 as the control means for controlling the whole of the sputtering apparatus includes a CPU 131 for executing various processing operations such as calculation, control and determination, and a ROM 132 for storing a control program for the processing that is executed by the CPU 131 and will be described below in FIG. 5. The control part 130 also has a RAM 133 for temporarily storing data during processing of the CPU 131, input data and the like.

An input operation part 134 including a keyboard or various switches for inputting a predetermined command or data and a display part 135 for displaying input/setting states and the like of the sputtering apparatus are connected to the control part 130. The DC power sources 110a to 110d, the shutter driving part 120 and the rotation driving part 121 are connected to the control part 130 via driving circuits 136 to 138, respectively.

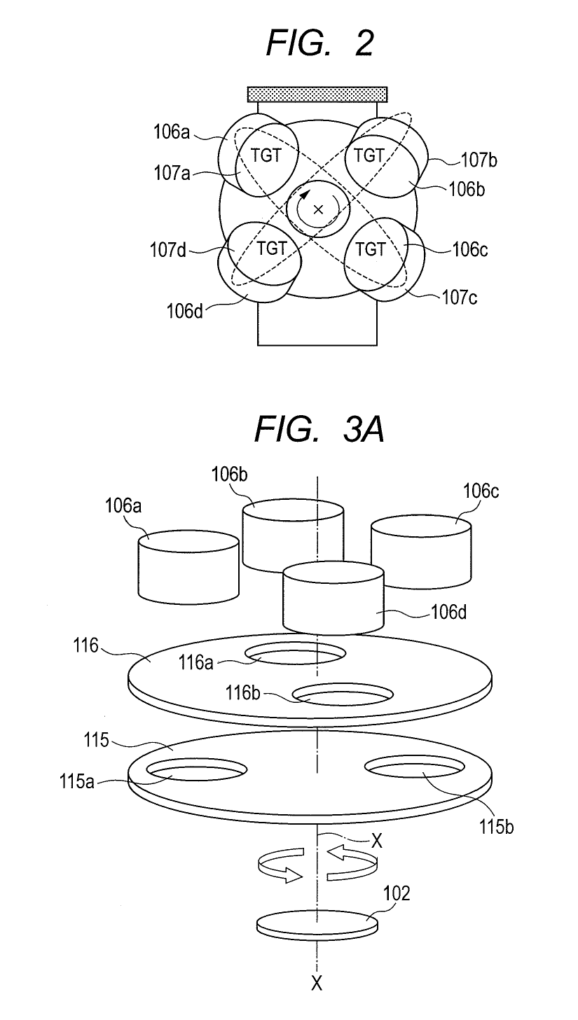

FIG. 2 is a top view showing the target holders. In this example, the target holders 107a, 107b, 107c and 107d for holding the four targets 106a, 106b, 106c and 106d, respectively, are provided. The target holder 107a and the target holder 107c are arranged symmetrically with each other with respect to a rotational axis X of the substrate holder 103. Similarly, the target holder 107b and the target holder 107d are arranged symmetrically with each other with respect to the rotational axis X of the substrate holder 103. In this example, the first type of targets 106a and 106c (for example, Fe) are mounted on the target holder 107a and the target holder 107c. These target holders 107a and 107c are referred to as first group target holders. On the target holder 107b and the target holder 107d, different from the targets 106a and 106c, the second type of targets 106b and 106d (for example, Pt) are mounted. These target holders 107b and 107d are referred to as second group target holders.

At formation of a first layer, the DC power sources 110a and 110c as the power supply means are configured to supply first electric power (for example, 600 W) to the target holder 107a and the target holder 107c that mount the first type of targets 106a and 106c (for example, Fe). At formation of a second layer, the DC power sources 110b and 110d as the power supply means are configured to supply second electric power (for example, 300 W) that is different from the first electric power, to the target holder 107b and the target holder 107d that mount the second type of targets 106b and 106d (for example, Pt). It is desired that the plurality of target holders 107a, 107b, 107c and 107d is individually provided with the DC power sources 110a, 110b, 110c and 110d, respectively.

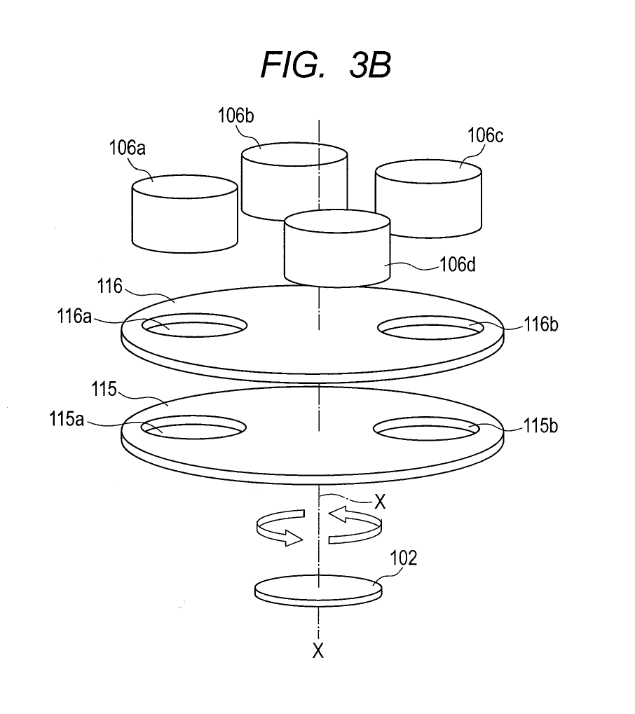

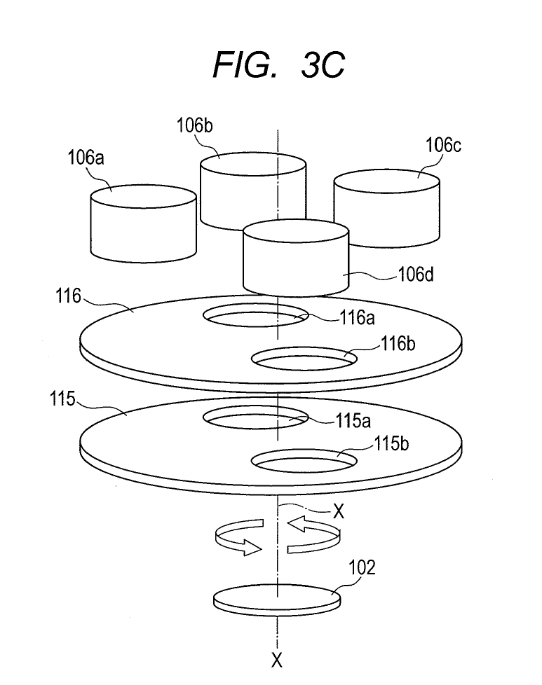

FIGS. 3A to 3C are schematic views illustrating detailed configuration of the shutters 115 and 116.

The second shutter 116 is provided with two-fold symmetrically arranged holes (openings) 116a, 116b, that is, when the shutter is rotated with respect to the rotational axis X by ½ rotation (180 degrees), the positions of the holes match the positions before rotation. Similarly, the first shutter 115 is provided with holes (openings) 115a, 115b two-fold symmetrically arranged with respect to the rotational axis X. The rotational axis of the first shutter 115, the rotational axis of the second shutter 116 and the rotational axis of the substrate 102 are arranged to be coaxial.

FIG. 3A shows the state where the shutters 115 and 116 shield all of the targets 106a, 106b, 106c and 106d against the substrate 102. Specifically, the second shutter 116 shields the targets 106a and 106c, and the holes 116a and 116b formed in the second shutter 116 are arranged opposed to the targets 106b and 106c, respectively. In the state shown in FIG. 3A, the first shutter 115 shields the holes 116a and 116b and the targets 106b and 106d against the substrate 102.

FIG. 3B shows the state where the targets 106a and 106c to be sputtered are opened to the substrate 102. That is, the holes 116a and 116b formed in the second shutter 116 are arranged opposite to the targets 106a and 106c. Similarly, the holes 115a and 115b formed in the first shutter 115 are arranged opposed to the targets 106a and 106c, respectively.

FIG. 3C shows the state where the targets 106b and 106d to be sputtered are opened to the substrate 102. That is, the holes 116a and 116b formed in the second shutter 116 are arranged opposed to the targets 106b and 106d, respectively. Similarly, the holes 115a and 115b formed in the first shutter 115 are arranged opposed to the targets 106b and 106d, respectively.

As described above, the first shutter 115 and the second shutter 116 can be opened/closed by bringing the targets to be opposed to the holes or shifting the targets from the holes through rotation with respect to the rotational axis by use of the shutter driving part 120. In this specification, “opened, opened state” means that a predetermined target is exposed to the substrate 102 via both the first shutter 115 and the second shutter 116 and is opened to the substrate 102 through the hole in the first shutter 115 and the hole in the second shutter 116. In this specification, “closed, closed state” means that a predetermined target is not exposed to the substrate 102 by at least one of the first shutter 115 and the second shutter 116, and is shielded against the substrate 102 by at least one of the first shutter 115 and the second shutter 116.

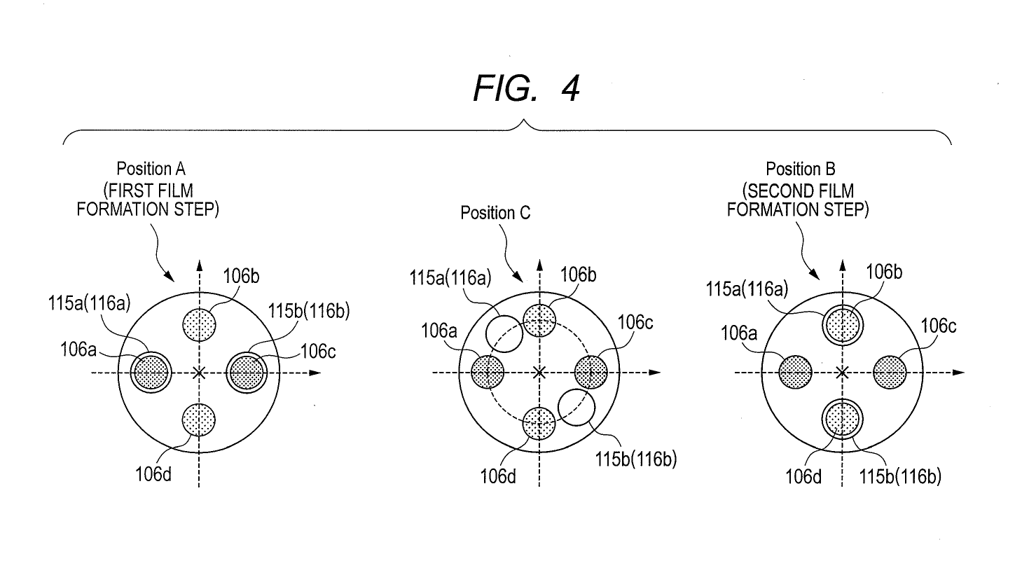

FIG. 4 is a schematic plan view illustrating positional relationship between the shutters 115 and 116 and each of the targets.

As shown in FIG. 3B, Position A in FIG. 4 shows the state (opened state) where the targets 106a and 106c to be sputtered are opened to the substrate 102. In this embodiment, the target holders 107a and 107c, the holes 115a and 115b and the holes 116a and 116b are positioned at Position A as a first rotational position of the holes 115a and 115b and the holes 116a and 116b so that the holes 115a and 115b and the holes 116a and 116b overlap the targets 106a and 106c. As shown in FIG. 3C, Position B in FIG. 4 shows the state (opened state) where the targets 106b and 106d to be sputtered are opened to the substrate 102. In this embodiment, the target holders 107b and 107d, the holes 115a and 115b and the holes 116a and 116b are positioned at Position B as a second rotational position of the holes 115a and 115b and the holes 116a and 116b so that the holes 115a and 115b and the holes 116a and 116b overlap the targets 106b and 106d.

Position C in FIG. 4 shows the state (closed state) where the holes 115a and 115b in the first shutter 115 and the holes 116a and 116b in the second shutter 116 do not overlap any target at an intermediate position between Position A in FIG. 4 and Position B in FIG. 4. As shown by Position C in FIG. 4, by creating the state where sputtering film formation is not performed from any target, adhesion of sputtering particles to the substrate 102 can be prevented or reduced. In this embodiment, Position C is important in that the closed state is established by using the first shutter 115 and the second shutter 116. Accordingly, as shown in FIG. 3A, even when at least one of the holes in the first shutter 115 or the holes in the second shutter 116 overlap the targets of interest, if the other do not overlap, the arrangement corresponds to Position C. That is, the position where the first shutter 115 and the second shutter 116 shield all of the targets 106a to 106d against the substrate 102 is referred to as Position C.

Although the two shutters 115 and 116 are used in this embodiment, the number of the shutters is not limited to two. That is, according to the present invention, in forming a film using the first type of targets, it is essential that each of the holes formed in the shutter is located opposed to each of the first type of targets, and each of the second type of targets is shielded by the shutter against the substrate. According to the present invention, in forming a film using the second type of targets, it is essential that each of the holes formed in the shutter is located opposed to each of the second type of targets, and each of the first type of targets is shielded by the shutter against the substrate. To achieve them, at least one shutter only needs to be used. Accordingly, one of the first shutter 115 and the second shutter 116 may be used and the other (another shutter) may not be used.

Next, referring to FIG. 5, a manufacturing method according to an embodiment of the present invention will be described.

FIG. 5 is a view illustrating an MRAM manufacturing method using the sputtering apparatus according to this embodiment. A manufacturing method of a laminated body obtained by alternately laminating two different layers (a first layer formed of the targets 106a and 106c and a second layer formed of the targets 106b and 106d) will be described below as an example. In this embodiment, Fe is used for the targets 106a and 106c and Pt is used for the targets 106b and 106d. However, target materials are not limited to these, a target material formed of an alloy containing one or more of following elements: Fe, Co and Ni may be adopted for the targets 106a and 106c. A target material formed of an alloy containing one or more of following elements: Cr, Pt, Pd, Ir, Rh, Ru, Os, Re, Au and Cu may be adopted for the targets 106b and 106d. Following treatment is performed by the control part 130 as the control means such as a computer mounted in the sputtering apparatus of the present invention.

In Step S100, this steps are started. That is, when the user inputs a command to start manufacturing an MRAM and information representing the number of the laminated layers M of the first layer and the second layer (M is a natural number, and the M first layers and the M second layers are formed) by means of the input operation part 134, the control part 130 accepts the user's input, allows the RAM 133 to store the number of the laminated layers M therein and performs a manufacturing procedure shown in FIG. 5 according to the start command. The control part 130 proceeds with three preparation treatment steps: substrate transfer, gas introduction and shutter shielding in parallel. That is, in Step S101, the control part 130 controls a transfer robot (not shown) to transfer the substrate 102 into the treatment chamber 100 and places the substrate 102 on the substrate holder 103. Next, in Step S103 (first preparation step), the control part 130 causes the rotation driving part 121 to rotate the substrate holder 103 at a predetermined rotational speed (in this example, 100 rpm).

In parallel with the above-mentioned treatment, in Step S104, the control part 130 causes the gas introducing part 201 to introduce process gas (inert gas such as argon gas) into the treatment chamber 100. In the above-mentioned treatment, that is, as shown in Step S105, the control part 130 drives the shutter driving part 120 to position the shutters 115 and 116 in the closed state as shown in FIG. 3A. That is, in this step, the control part 130 controls the shutter driving part 120 to rotate and position the first shutter 115 and the second shutter 116 at Position C, that is, so that the holes 116a and 116b in the shutter 116 overlap the targets 106b and 106d and the holes 115a and 115b in the shutter 115 do not overlap the targets 106a and 106c.

In Step S106 (second preparation step), the control part 130 controls the DC power sources 110a to 110d to supply predetermined electric power to the target holders 107a to 107d. That is, the first electric power is supplied from the DC power sources 110a and 110c to the target holders 107a and 107c, and the second electric power is supplied from the DC power sources 110b and 110d to the target holders 107b and 107d. Thereby, argon gas in the treatment chamber 100 is plasma discharged. As described above, wastage of the targets can be suppressed by performing a power supply step after the three preparation treatment steps of substrate transfer, gas introduction and shutter shielding.

In Step S107 (first film formation step), by bringing the shutters 115 and 116 into the state shown in FIG. 3B, sputtering film formation of the targets 106a and 106c (formation of the first layer) is started. That is, in this step, the control part 130 controls the shutter driving part 120 to rotate and position the first shutter 115 and the second shutter 116 at Position A in FIG. 4, so that the holes 116a and 116b in the shutter 116 and the holes 115a and 115b in the second shutter 115 overlap the targets 106a and 106c. When film formation continues for a predetermined time, the procedure proceeds to a next step.

In Step S108 (second film formation step), by rotating the shutters 115 and 116 by 90 degrees to bring the shutters 115 and 116 into the state shown in FIG. 3C, sputtering film formation of the targets 106b and 106d (film formation of the second layer) is started. That is, in this step, the control part 130 controls the shutter driving part 120 to rotate and position the first shutter 115 and the second shutter 116 at Position B in FIG. 4, that is, so that the holes 116a and 116b in the shutter 116 and the holes 115a and 115b in the second shutter 115 overlap the targets 106b and 106d. When film formation continues for a predetermined time, the procedure proceeds to a next step.

In Step S109, the control part 130 determines whether or not the number of films currently formed reached a predetermined number of laminated layers M. In this embodiment, each time Step S108 is finished, the control part 130 counts the number of films currently formed and causes the RAM 133 to store the count value therein. That is, when predetermined time for the first film formation step and the second film formation step has elapsed, the control part 130 increments the count value corresponding to the number of the laminated layers and causes the RAM 133 to store the accumulated count value as the current number of laminated layers therein. Thus, in this step, the control part 130 compares the number of the laminated layers M stored in the RAM 133 with the count value to determine whether or not the number of the laminated layers currently formed reached the predetermined number of laminated layers M. When the determination result represents No, the procedure returns to Step S107, and film formation treatment is repeated. “Repeat” described herein means that at least the first film formation step, the second film formation step and the first film formation step are performed in this order.

When the determination result represents No in this step and the procedure returns to Step S107, there are cases where the first shutter 115 and the second shutter 116 rotate by 90 degrees in the same direction as the direction at transition from Step S107 to Step S108 and in the reverse direction to the direction at transition from Step S107 to Step S108. In the case of rotation in the same direction, the shutter driving part 120 needs to have only a rotational mechanism for rotating the first shutter 115 and the second shutter 116 in the same direction. In the case of rotation in the reverse direction, since a film adhering to the surface of the shutter on the target side is not laminated on the different type of film, it is advantageously easy to release the film after replacement of the shutter.

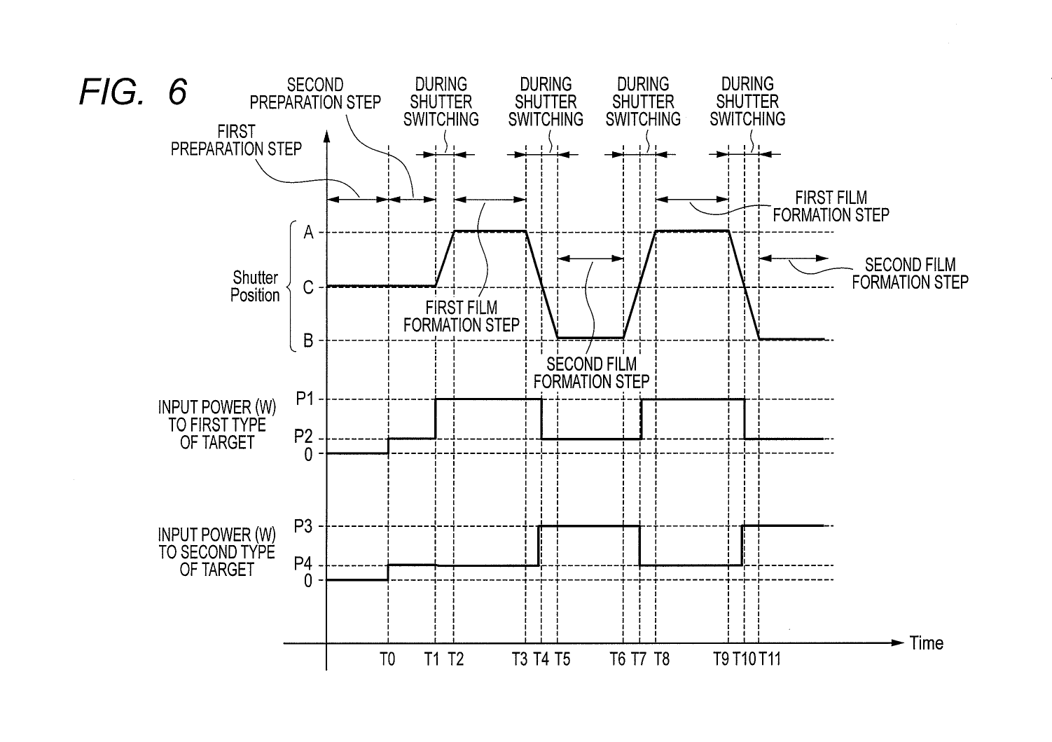

Here, referring to FIG. 4, FIG. 5 and FIG. 6, time required to perform the repeating operations of formation of the first layer and formation of the second layer will be described.

The first shutter 115 and the second shutter 116 are kept, for example, in the state representing Position C in FIG. 3A till Time T1. At Time T1, as shown in FIG. 6, the shutter 116 is operated for about one second (Time T1 to T2) to establish Position A. Thereby, the targets 106a and 106c are completely opened to the substrate 102 and brought into the state shown in FIG. 3B (Position A) and at Time T2, the first film formation step for a predetermined time is started. Next, at Time T3, the shutters 115 and 116 rotate with respect to the rotational axis X in sync with each other and are brought into the state at Position C in FIG. 4, that is, the state where sputtering particles from the first type of targets 106a and 106c as well as sputtering particles from the second type of targets 106b and 106d are shielded by the shutters 115 and 116 against the substrate 102. After that, at Time T5, the shutters 115 and 116 are brought into the state shown in FIG. 3C (Position B), and the second film formation step for a predetermined time from Time T5 is started. Then, after the shutter operation for a predetermined time from Time T6, the first film formation step is performed from Time T8 to T9. Further, after the shutter operation for a predetermined time from Time T9 to T11, the second film formation step is performed. In this manner, the predetermined number of laminated films are formed. The shutters may be moved at a constant speed as shown in FIG. 6, or may operate at low speed immediately after the film formation time, operate at high speed when passing Position C and operate at low speed again when getting close to Position A. Through such operation, at immediately after end and start of the film formation steps, when the film formation speed transiently varies, control performance of the film formation speed can be improved, thereby enabling more accurate film thickness distribution control.

FIG. 6 further shows relationship between electric power supplied to the first type of targets 106a and 106c, electric power supplied to the second type of targets 106b and 106d and time. The DC power sources 110a and 110c may continue to supply constant electric power (for example, 600 W) to the first type of targets (target holders 107a and 107c), and the DC power sources 110b and 110d may continue to supply constant electric power (for example, 300 W) to the second type of targets (target holders 107b and 107d). However, this greatly wastes targets that do not contribute to forming a film and electric power is uselessly consumed. For this reason, in this example, the DC power sources as the power supply means supply reduced electric power to the targets that do not contribute to forming a film.

Specifically, as shown in FIG. 6, in the above-mentioned second preparation step, at Time T0, DC power sources 110a and 110c supply electric power P2 (50 W) to the first type of targets 106a and 106c (target holders 107a and 107c), while the DC power sources 110b and 110d supply electric power P4 (50 W) to the second type of targets 106b and 106d (target holders 107b and 107d). When the shutters 115 and 116 are opened to start the first film formation step, the DC power sources 110a and 110c increase the electric power P2 supplied to the first type of targets 106a and 106c to electric power P1 at Time T1, while the DC power sources 110b and 110d maintain the electric power P4 supplied to the second type of targets 106b and 106d as it is.

Further, at Time T4 during transition from Position A to Position B, the DC power sources 110a and 110c decrease the electric power P1 supplied to the first type of targets 106a and 106c to the electric power P2, the DC power sources 110b and 110d increase the electric power P4 supplied to the second type of targets 106b and 106d to electric power P3. As a result, at Time T5, the second type of targets 106b and 106d are opened to the substrate 102, the electric power P3 necessary for forming the second layer is applied to the substrate holders 107b and 107d and the second film formation step is performed.

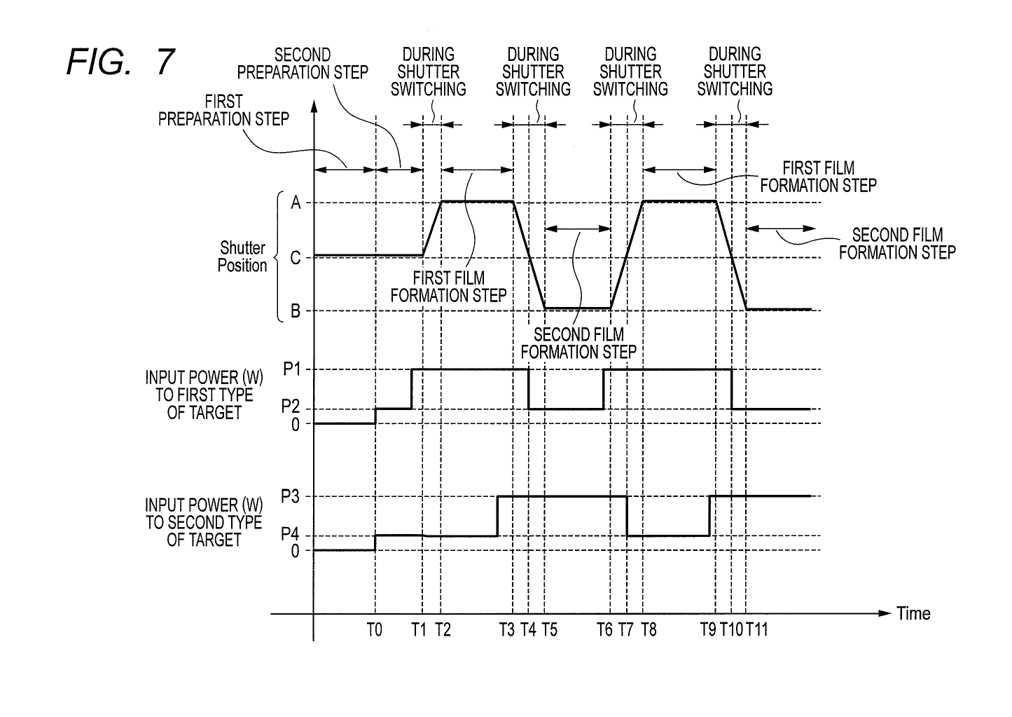

As described above, decreasing the electric power applied to the group of targets that do not contribute to forming a film (to about 50 W) by the DC power sources as the power supply means allows to suppress useless consumption of the targets. In FIG. 6, although the timing of applying electric power to the various targets is set to the time when the shutters 115 and 116 pass Position C, the timing is not limited to the time and may be earlier as shown in FIG. 7.

As described above, when Yes is determined in Step S109, that is, the predetermined number of laminated layers M is achieved, the procedure proceeds to Step S110 and the film formation treatment is finished.

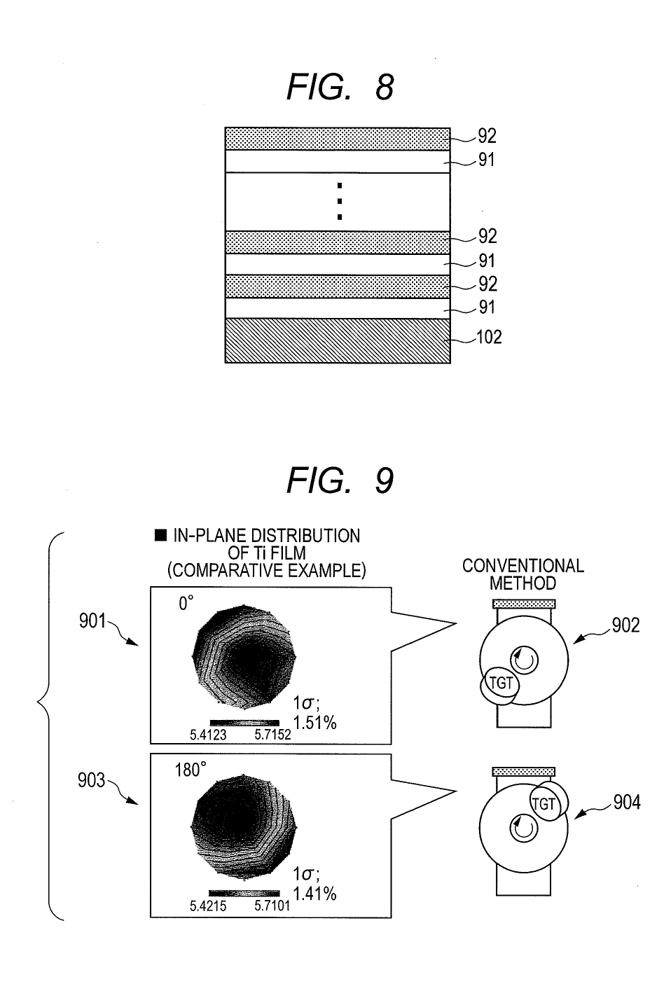

FIG. 8 shows a Fe/Pt artificial superlattice prepared according to this manufacturing method. In FIG. 8, a reference numeral 91 denotes the first layer and a reference numeral 92 denotes the second layer. The configuration of the artificial superlattice is not limited to this, and may be any configuration in which an alloy containing one or more elements of Fe, Co and Ni and an alloy containing one or more elements of Cr, Pt, Pd, Ir, Rh, Ru, Os, Re, Au and Cu are alternately laminated. For example, a Co/Pt artificial superlattice, a Co/Pd artificial superlattice, a CoCr/Pt artificial superlattice, a Co/Ru artificial superlattice and a Co/Os, Co/Au, Ni/Cu artificial superlattice may be employed.

By sputtering the opposed targets in this manner, a uniform film can be formed on the substrate. In this embodiment, the target holders 107a and 107c for holding the first type of targets 106a and 106c are located two-fold symmetrical with respect to the rotational axis X, and the target holders 107b and 107d for holding the second type of targets 106b and 106d are located two-fold symmetrical with respect to the rotational axis X. Further, the first shutter 115 and the second shutter 116 are configured so that the holes 115a and 115b are located two-fold symmetrical with respect to the rotational axis X, and the holes 116a and 116b are located two-fold symmetrical with respect to the rotational axis X. Moreover, each of the holes 115a and 115b and the holes 116a and 116b is positioned so as to overlap each of the targets 106a to 106d. Accordingly, by continuing the operation of rotating the shutters by a predetermined angle (in this example, 90 degrees), a uniform laminated film can be manufactured with high throughputs.

FIG. 9 shows in-plane distribution of a film formed by oblique sputtering as a comparative example. Specifically, a reference numeral 901 represents in-plane distribution of a Ti film in the case where oblique sputtering is performed using one Ti target while rotating the substrate as shown in conventional configuration 902. It is assumed that the total number of revolutions of the substrate holder during film formation is 100. In a reference numeral 903, as shown in conventional configuration 904, oblique sputtering is performed using a target shifted from the position of the target in the conventional configuration 902 by 180 degrees with respect to the rotational axis while rotating the substrate. For the conventional configuration 902 and the conventional configuration 904, an experiment is made under the same conditions except for the position of the target. An experiment result demonstrates that, as shown by the in-plane distribution 901 and 903, in-plane distribution is nonuniform. This is due to, as shown in FIG. 6, the opening operation of the shutter.

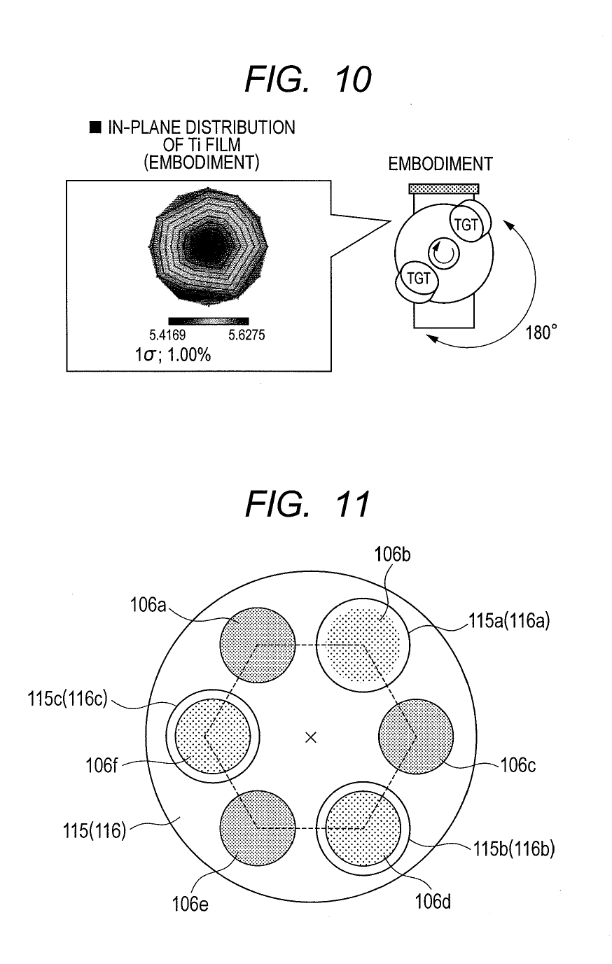

FIG. 10 shows in-plane distribution of the film formed according to this embodiment. Specifically, oblique sputtering is performed using Ti targets held in the opposed target holders 106a and 106c while rotating the substrate. This demonstrates that, by performing sputtering film formation using the two targets arranged two-fold symmetrical with respect to a predetermined axis (rotational axis X), imbalance in the film due to the opening operation of the shutter as in the comparative example is compensated, thereby forming a concentric uniform Ti film.

In this embodiment, the rotational axis of the substrate holder 103 matches the rotational axes of the first shutter 115 and the second shutter 116. Two targets as materials for a film to be formed are arranged in two-fold symmetry with respect to the matched rotational axis X, the holes 115a and 115b are arranged two-fold symmetrical with respect to the rotational axis X and the holes 116a and 116b are also arranged two-fold symmetrical with respect to the rotational axis X. Accordingly, since the two targets that form the film are exposed at the position two-fold symmetrical with respect to the rotational axis X of the substrate holder 103 in the opened state, imbalance in the film can be compensated, so that in-plane distribution can be made concentric and uniform.

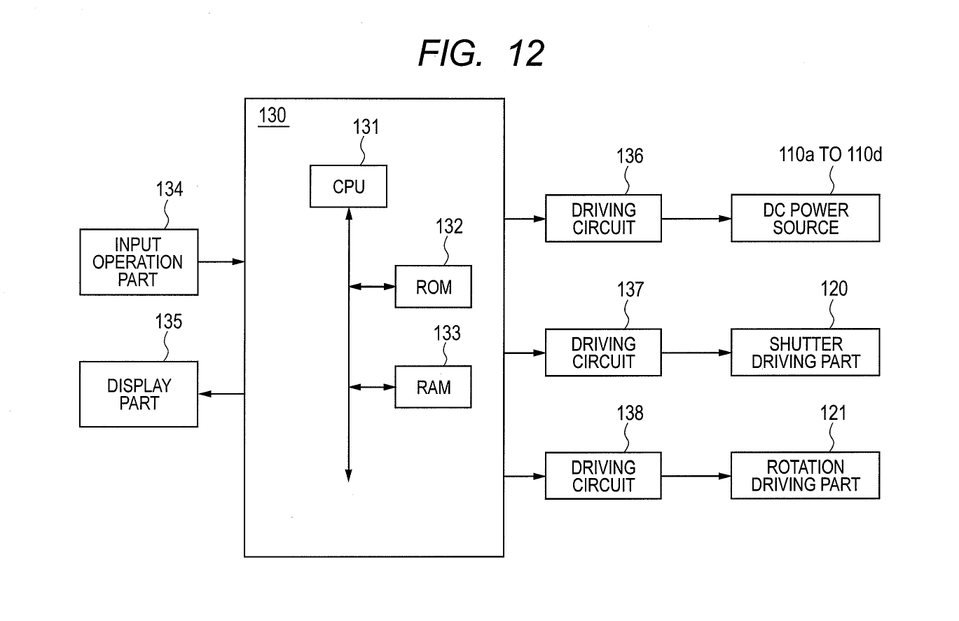

FIG. 11 is a plan view illustrating a modification example of the target holders.

FIG. 2 shows the targets 106a and 106c arranged 180 degrees symmetrical with respect to the rotational axis X (two-fold symmetry) and the targets 106b and 106d arranged between the targets 106a and 106c and 180 degrees symmetrical with respect to the rotational axis X (two-fold symmetry). FIG. 10 shows the targets 106a and 106c, 106e arranged 120 degrees symmetrical with respect to the rotational axis X (three-fold symmetry) and targets 106b, 106d and 106f arranged between targets 106a, 106c and 106e (between the first group target holders) and arranged 120 degrees symmetrical with respect to the rotational axis X (three-fold symmetry). In this case, holes 115a, 115b and 115c formed in the shutter 115 are arranged three-fold symmetrical with respect to the rotational axis X. Similarly, holes 116a, 116b and 116c formed in the shutter 116 are arranged three-fold symmetrical with respect to the rotational axis X.

The number of the first group target holders that can be applied to the present invention is not limited to two and three, and may be n (n is an integer of two or more). In this case, it is needed to arrange each of the first group target holders n-fold symmetrical (in n-fold symmetry) with respect to the rotational axis X of the substrate holder. Similarly, the number of the second group target holders is n and it is needed to arrange each of the second group target holders n-fold symmetrical (in n-fold symmetry) with respect to the rotational axis X of the substrate holder. Similarly, the number of the holes formed in the shutter is n and it is needed to arrange each of the holes n-fold symmetrical (in n-fold symmetry) with respect to the rotational axis X. The number of the shutters is not limited to two, and may be one or three or more.

As described above, in the embodiment of the present invention, the n first group target holders for forming the first layer are arranged n-fold symmetrical (in n-fold symmetry) with respect to the rotational axis X of the substrate holder, and the n second group target holders for forming the second layer are arranged n-fold symmetrical (in n-fold symmetry) with respect to the rotational axis X. In addition, the shutters that can rotate about the rotational axis X and have n holes provided so as to overlap the first group target holders and the second group target holders according to rotation are provided between the target holders and the substrate holder, and the n holes are arranged n-fold symmetrical (in n-fold symmetry) with respect to the rotational axis X. Accordingly, for example, in forming the first layer, the targets held in the first group target holders can be opened to the substrate held in the substrate holder from the position n-fold symmetrical with respect to the rotational axis X. As a result, imbalance in the film can be compensated, and in-plane distribution can be made concentric and uniform.

What is claimed is:

1. A sputtering apparatus comprising:
a treatment chamber;
a substrate holder for holding a substrate, the substrate holder being provided in the treatment chamber and being configured so as to be rotatable about a rotational axis perpendicular to a film formation surface of the substrate;
a target holder group provided in the treatment chamber, the target holder group configured to be capable of holding a target and provided so that the rotational axis does not match a perpendicular line passing the center of the target; and
a shutter provided between the target holder group and the substrate holder, the shutter being capable of rotating about the rotational axis and having n holes arranged n-fold symmetrical with respect to the rotational axis, wherein
the target holder group includes n first group target holders arranged n-fold symmetrical with respect to the rotational axis and n second group target holders arranged n-fold symmetrical with respect to the rotational axis, each of the second group target holders being provided between the first group target holders, and
each of the n first group target holders overlaps each of the n holes at a first rotational position of the n holes, and each of the n second group target holders overlaps each of the n holes at a second rotational position of the n holes.

2. The sputtering apparatus according to claim 1, further comprising:
a rotation driving means for rotating the substrate holder about the rotational axis;
a shutter driving means for rotating the shutter about the rotational axis;
a power supply means for supplying electric power to the target holder group; and
a control means for controlling the rotation driving means, the power supply means and the shutter driving means, wherein
when a laminated body obtained by alternately laminating a first layer and a second layer is formed, the control means
drives the rotation driving means to start rotation of the substrate holder,
drives the power supply means to supply first electric power to the first group target holders and supply second electric power to the second group target holders,
in forming the first layer, drives the shutter driving means to position the n holes in the shutter as opposed to the first group target holders, and
in forming the second layer, drives the shutter driving means to position the n holes in the shutter as opposed to the second group target holders.

3. The sputtering apparatus according to claim 1, further comprising
another shutter provided between the target holder group and the substrate holder, the another shutter being capable of rotating about the rotational axis and having n holes arranged n-fold symmetrical with respect to the rotational axis, wherein
each of the n holes in the another shutter overlaps each of the first group target holders and each of the second group target holders according to a rotational position of the another shutter.

4. The sputtering apparatus according to claim 3, further comprising:
a shutter driving means for rotating the shutter and the another shutter about the rotational axis; and
a control means for controlling the shutter driving means, wherein
when a laminated body obtained by alternately laminating a first layer and a second layer is formed, the control means
controls the shutter driving means so that the n holes in the shutter do not overlap the n holes in the another shutter prior to formation of the first layer and the second layer.

5. The sputtering apparatus according to claim 4, further comprising:
a rotation driving means for rotating the substrate holder about the rotational axis; and
a power supply means for supplying electric power to the target holder group, wherein
the control means is configured to also control the rotation driving means and the power supply means, and
the control means is configured to drive the rotation driving means to start rotation of the substrate holder prior to formation of the first layer and the second layer and then, drive the power supply means to supply first electric power to the first group target holders and to supply second electric power to the second group target holders.

6. The sputtering apparatus according to claim 2, wherein
the control means decreases the electric power supplied to the second group target holders in forming the first layer, and decreases the electric power supplied to the first group target holders in forming the second layer.

7. A manufacturing method of an electronic device using a sputtering apparatus including:
a treatment chamber;
a substrate holder for holding a substrate, the substrate holder being provided in the treatment chamber and being configured so as to be rotatable about a rotational axis perpendicular to a film formation surface of the substrate;
a target holder group provided in the treatment chamber, the target holder group configured to be capable of holding a target and provided so that the rotational axis does not match a perpendicular line passing the center of the target; and
a shutter provided between the target holder group and the substrate holder, the shutter being capable of rotating about the rotational axis and having n holes arranged n-fold symmetrical with respect to the rotational axis, wherein
the target holder group includes n first group target holders arranged n-fold symmetrical with respect to the rotational axis and n second group target holders arranged n-fold symmetrical with respect to the rotational axis, each of the second group target holders being provided between the first group target holders, and
each of the n first group target holders overlaps each of the n holes at a first rotational position of the n holes, and each of the n second group target holders overlaps each of the n holes at a second rotational position of the n holes,
the manufacturing method comprising:
a first preparation step of starting rotation of the substrate holder;
a second preparation step of supplying first electric power to the first group target holders and supplying second electric power to the second group target holders,
a first film formation step of positioning the n holes in the shutter as opposed to the first group target holders; and
a second film formation step of positioning the n holes in the shutter as opposed to the second group target holders.

8. The manufacturing method of an electronic device according to claim 7, wherein the first film formation step and the second film formation step are repeated.
